(19) United States
(12) Patent Application Publication
(10) Pub. No.: US 2007/0196772 A1
(43) Pub. Date: Aug. 23, 2007

(54) METHOD FOR FORMING FINE PATTERN OF SEMICONDUCTOR DEVICE

(75) Inventor: Jae Chang Jung, Seoul (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 11/567,215

(22) Filed: Dec. 6, 2006

(30) Foreign Application Priority Data
Feb. 23, 2006 (KR) 10-2006-0017692

(51) Int. Cl. G03F 7/26

(52) U.S. Cl. 430/311; 430/330

(57) ABSTRACT

A method for forming a fine pattern of a semiconductor device comprises: forming a photoresist layer including a first photoresist pattern region having a first pattern density and a second photoresist pattern region having a second pattern density which is denser than the first pattern density; performing an exposure process selectively exposing one of the first and the second photoresist pattern regions with an exposure mask; and performing a resist flow process on the resulting structure.

### CROSS-REFERENCES TO RELATED APPLICATIONS

The present application claims priority to Korean patent application number 10-2006-0017692, filed on Feb. 23, 2006, which is incorporated by reference in its entirety.

### BACKGROUND OF THE INVENTION

The present invention relates to a method for forming a fine pattern in a semiconductor device.

As the technology of manufacturing semiconductor devices has developed and the field of memory devices has been extended, there has been urgent need to improve the integration of high-capacity memory devices while maintaining the electrical characteristics. As a result, multilateral studies to improve the photo-lithography process, cell structures, and physical property limits of materials used in wires and insulating films have been made.

The currently used photo-lithography process utilizes an exposer with short wavelength light sources such as KrF and ArF. However, since the resolution of the exposer with the short wavelength light source is limited to 0.1 μm, it is difficult to form fine patterns needed for highly integrated semiconductor devices.

### BRIEF SUMMARY OF THE INVENTION

Embodiments of the present invention are directed at a method for forming a fine pattern of a semiconductor device.

In one embodiment, a method for forming a fine pattern includes performing a resist flow process selectively on a predetermined region depending on the difference of the photoresist pattern density

A method for forming a fine pattern in a semiconductor device comprises: forming a photoresist layer including a first photoresist pattern region having a first pattern density and a second photoresist pattern region having a second pattern density which is denser than the first pattern density; performing an exposure process with an exposure mask where only one of the first and second photoresist pattern regions is open to expose only one of the first and second photoresist pattern regions; and performing a resist flow process on the resulting structure.

### BRIEF DESCRIPTION OF THE DRAWINGS

FIG. 1 is a SEM photograph illustrating a photoresist pattern obtained from one embodiment of resist flow process.

FIG. 2 is a SEM photograph illustrating a photoresist pattern obtained from a method for forming a fine pattern according to a specific embodiment of the present invention.

### DESCRIPTION OF SPECIFIC EMBODIMENTS

The present invention relates to a method for forming a fine pattern in a semiconductor device.

In order to obtain a fine contact hole pattern having better resolution over the exposer during the photo-lithography, (i) a resist flow process [Japanese Journal of Applied Physics. Vol. 37, pp. 6863-6868 (1998)] or (ii) a coating treatment process with SAFIER™ (Shrink Assist Film for Enhanced Resolution) materials produced by TOK Co. [Advances in Resist Technology and Processing XXI. Edited by Sturtevant, John L. Proceedings of the SPIE, Volume 5376, pp. 533-540 (2004)] have been developed.

According to the resist flow process, thermal energy is applied to the photoresist pattern obtained from an exposure and developing process at or above the glass transition temperature (Tg) until the photoresist may flow thermally so as to reduce the size of the photoresist pattern holes.

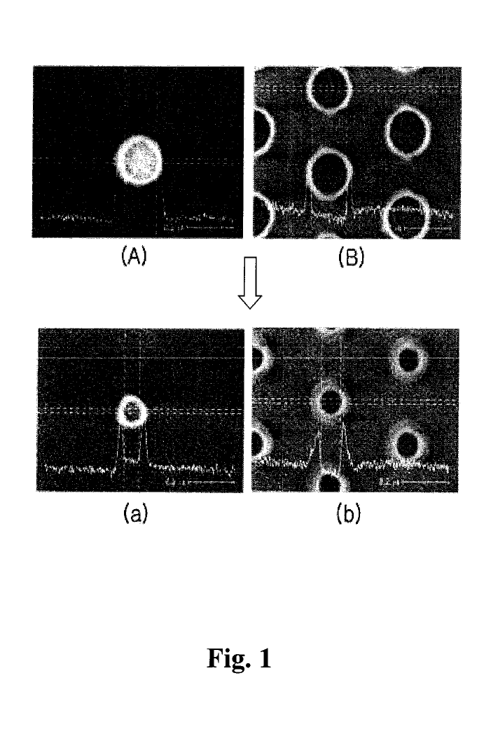

FIG. 1 illustrates a SEM photograph illustrating the photoresist pattern obtained from a resist flow process.

A photoresist composition is coated over an underlying layer. The resulting structure is baked at 110° C. for about 90 seconds to form a photoresist film.

An exposure process is performed on the photoresist film with an energy of 5 mJ/cm² or more. The exposure process is performed with an exposure mask having two kinds of open pattern density regions, so that a first photoresist pattern region having a first pattern density (that is, the number of open holes in an unit area) and a second pattern region having a second pattern density relatively denser than the first pattern density can be formed.

The resulting structure is baked at 110° C. for about 90 seconds, and developed with 2.35 wt % developing solution.

As a result, a photoresist pattern layer is formed which has a first photoresist pattern region A having the first pattern density and a second photoresist pattern region B having the second pattern density denser than the first pattern region (or first pattern density).

The size of the holes in the above photoresist pattern is 310 nm.

When the resist flow process is performed to bake the resulting structure at or above the glass transition temperature, holes of the first photoresist pattern region A and the second photoresist pattern B are reduced in size so that the first photoresist pattern region a and the second photoresist pattern region b having contact hole patterns reduced to the same size of about 100 nm are formed.

In an embodiment of the present invention, a method for forming a fine pattern of a semiconductor device comprises forming photoresist layer (or photoresist layer) including a first photoresist pattern region having a first pattern density and a second photoresist pattern region having a second pattern density which is denser than the first pattern density. An exposure process is performed with an exposure mask where only one of the first and second photoresist pattern regions is open to expose only one of the first and second photoresist pattern region. A resist flow process is performed on the resulting structure after removing the exposure mask to form a fine pattern.

According to one embodiment of the present invention, resist flow only occurs in an unexposed region during the resist flow process. As a result, a photoresist pattern with a higher resolution is formed in the unexposed region, thereby obtaining photoresist pattern layers each having a different size depending on density.

The present invention will be described in detail with reference to the accompanying drawings.

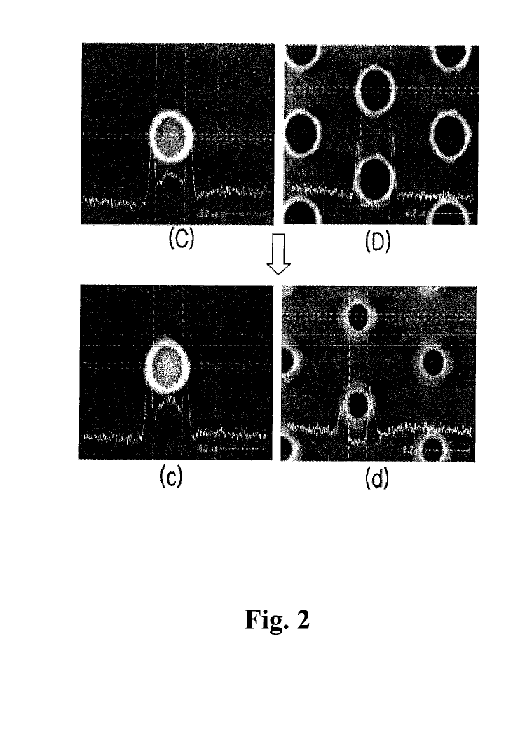

FIG. 2 is a SEM photograph illustrating a photoresist pattern obtained from a method for forming a fine pattern according to a specific embodiment of the present invention.

A photoresist composition is coated over an underlying layer, and soft-baked at 110° C. for about 90 seconds to obtain a photoresist film.

Any kinds of underlying layers can be used. For example, the underlying layer can be selected from the group consisting of polysilicon, oxide (SiO), nitride (SiON) and metals such as tungsten (W) or aluminum (Al).

The photoresist comprises a chemical amplified-type photoresist polymer having an acid labile group, and any chemical amplified-type photoresist polymers having a carboxyl acid as terminal group formed by abscission reaction of functional group can be used. For example, the photoresist includes a polymer selected from the group consisting of a ROMA-type polymer including a Ring-Opened Maleic Anhydride repeating unit; COMA-type polymer including Cyclo-Olefin repeating unit, Maleic Anhydride repeating unit and methacrylate or acrylate repeating unit; and hybrid-type polymer thereof. In this embodiment of the present invention, a ROMA-type ArF photoresist, A52T3 photoresist (produced by Geumho Petrochemicals), is used.

A first exposure process is performed on the photoresist film.

The first exposure process is performed using an exposure light selected from the group consisting of KrF (248 nm), ArF (193 nm), VUV (157 nm), EUV (13 nm), E-beam, X-ray and ion-beam with an exposure energy ranging from 5 to 300 mJ/cm².

The first exposure process is performed with a first exposure mask where a first pattern region or a more dense second pattern region is open to form residual images of the first and second photoresist patterns.

After the first exposure, the method may further include performing a post-baking process on the photoresist film.

The soft or post baking process may be performed at a temperature ranging from 70 to 200° C.

A developing process is performed using an alkali developing solution such as 0.01˜5 wt % tetramethyl ammonium hydroxide (TMAH) aqueous solution.

As a result, a photoresist pattern layer of about 110 nm in size is formed which includes a first photoresist pattern region C having a first pattern density and a second photoresist pattern region D having a more dense second pattern density.

A second exposure process is performed on the photoresist layer using a second exposure mask where only one of the first photoresist pattern region C or the second photoresist pattern region D is open.

The conditions of the second exposure process are the same as those of the first exposure process.

The resist flow process is performed on the resulting structure at or above the glass transition temperature of the photoresist, so as to reduce the minimum size photoresist pattern of the unexposed region by about 5% to 20%.

The conditions of the resist flow process can be adjusted with reference to the content described in Japanese Journal of Applied Physics. (Vol. 37, pp. 6863-6868 (1998)). When the glass transition temperature of the photoresist polymer ranges from 140 to 170° C., the resist flow process is performed at 140˜200° C. for 1˜90 seconds.

As a result, while resist flow does not occur in the exposed region, resist flow occurs selectively in the unexposed region.

For example, when the second exposure process is performed with the exposure mask where the first photoresist pattern region is open, the resist flow does not occur in the first photoresist pattern region c during the resist flow process. On the other hand, resist flow occurs in the second photoresist pattern region d which is the unexposed region, thereby obtaining the photoresist patterns reduced by about 90 nm.

Since a carboxyl acid is generated in the photoresist of the exposed region during the second exposure process, the glass transition temperature is increased. Therefore, resist flow does not occur in the exposed region even when a thermal energy is applied at or above the glass transition temperature of the photoresist. On the other hand, since the photoresist in the unexposed region has an essential property of photoresist, the resist flow occurs in the unexposed region during the resist flow process.

Also there is provided a semiconductor device fabricated by the above-described method for manufacturing a semiconductor device.

The above-described patterns will be described in detail by referring to the examples below, which are not intended to be limiting of this disclosure.

### COMPARATIVE EXAMPLE 1

An oxide for the underlying layer was formed over a silicon wafer treated with hexamethylsilazane (HMDS), and ArF photoresist (KUPR-A52T3G1, produced by Geumho Petrochemicals) was spin-coated at a thickness of 250 nm. The resulting structure was soft-baked at about 110° C. for about 90 seconds to form a photoresist film. After baking, the photoresist film was exposed using an ArF exposer (XT 1400E, produced by ASML Co.) and a first exposure mask where a first photoresist pattern density region and a more dense second photoresist pattern density region were open with an energy of 23 mJ/cm². The resulting structure was post-baked at 110° C. for 90 seconds.

After the post-baking was completed, the resulting structure was developed in 2.38 wt % TMAH solution for about 30 seconds, to obtain a 110 nm photoresist layer where a first photoresist pattern region A and a more dense second photoresist pattern region B are formed (see FIG. 1).

The resulting structure was baked at 148° C. for 60 seconds to flow the photoresist, thereby obtaining a 90 nm photoresist contact hole pattern where the holes in the first photoresist pattern region a and the second photoresist pattern region b are reduced to the same size (see FIG. 1).

### EXAMPLE 1

An oxide for the underlying layer was formed over a silicon wafer treated with HMDS, and ArF photoresist (KUPR-A52T3G1, produced by Geumho Petrochemicals) was spin-coated at a thickness of 250 nm. The resulting structure was soft-baked at about 110° C. for about 90 seconds to form a photoresist film. After baking, the photoresist film was exposed using an ArF exposer (XT 1400E, produced by ASML Co.) and a first exposure mask where a first photoresist pattern density region and a more dense second photoresist pattern density region were open with an energy of 23 mJ/cm². The resulting structure was post-baked at 110° C. for 90 seconds.

After the post-baking was completed, the resulting structure was developed in 2.38 wt % TMAH solution for about 30 seconds, to obtain 110 nm photoresist pattern layer where a first pattern region C and a more dense second pattern region D are formed (see FIG. 2).

A second exposure process was performed on the resulting structure using an exposure mask where the first pattern region C was open with an energy of 70 mJ/cm².

After the exposure process, the resulting structure was baked at 148° C. for 60 seconds to flow the photoresist. As a result, resist flow did not occur in the exposed first photoresist pattern region c, but resist flow occurred in the unexposed second pattern region d as, thereby obtaining a 90 nm photoresist contact hole pattern in the second photoresist pattern region d.

### EXAMPLE 2

An oxide for the underlying layer was formed over a silicon wafer treated with HMDS, and ArF photoresist (KUPR-A52T3G1, produced by Geumho Petrochemicals) was spin-coated at a thickness of 250 nm. The resulting structure was soft-baked at about 110° C. for about 90 seconds to form a photoresist film. After baking, the photoresist film was exposed using an ArF exposer (XT 1400E, produced by ASML Co.) and a first exposure mask where a first photoresist pattern density region and a more dense second pattern density region were open with an energy of 23 mJ/cm². The resulting structure was post-baked at 110° C. for 90 seconds.

After the post-baking was completed, the resulting structure was developed in 2.38 wt % TMAH solution for about 30 seconds, to obtain a 110 nm photoresist layer where a first photoresist pattern density region and a second photoresist pattern density region having pattern density relatively denser than the first pattern region are formed.

A second exposure process was performed on the resulting structure using an exposure mask where the second pattern region was open with an energy of 70 mJ/cm².

After the exposure process, the resulting structure was baked at 148° C. for 60 seconds to flow the photoresist. As a result, resist flow did not occur in the exposed second photoresist pattern region, but resist flow occurred in the unexposed first pattern region, thereby obtaining a 90 nm photoresist contact hole pattern in the first photoresist pattern region.

As described above, according to an embodiment of the present invention, a method for forming a fine pattern of a semiconductor device comprises forming a photoresist layer including two kinds of photoresist patterns each having a different density, performing an exposure process depending on the density difference and then performing a resist flow process to reduce the photoresist pattern selectively in an unexposed region.

The foregoing description of various embodiments of the invention has been presented for purposes of illustration and description. It is not intended to be exhaustive or to limit the invention to the precise form disclosed. Modifications and variations are possible in light of the above teachings or may be acquired from practice of the invention. The embodiments were chosen and described in order to explain the principles of the invention and its practical application to enable one skilled in the art to utilize the invention in various embodiments and with various modifications as are suited to the particular use contemplated.

What is claimed is:

1. A method for forming a fine pattern of a semiconductor device, the method comprising:
forming a photoresist layer including a first photoresist pattern region having a first pattern density and a second photoresist pattern region having a second pattern density which is denser than the first pattern density;
performing an exposure process with an exposure mask where only one of the first and second photoresist pattern regions is open to expose only one of the first and second photoresist pattern regions; and
performing a resist flow process on the resulting structure.

2. The method according to claim 1, wherein a resist flow does not occur in the one of the first and second photoresist pattern regions that is exposed during a resist flow process, and the resist flow occurs in the other photoresist pattern region that is not exposed.

3. The method according to claim 1, wherein the forming-photoresist layer step includes:
coating a photoresist composition over an underlying layer of a semiconductor substrate;
baking the photoresist composition to form a photoresist film;
performing an exposure process on the photoresist film with an exposure mask including a first open hole part having a first pattern density and a second open hole part having a second pattern density which is relatively denser than the first pattern density; and
performing a developing process on the resulting structure to form the first photoresist pattern having the first pattern density and second photoresist pattern having the second pattern density.

4. The method according to claim 3, wherein the photoresist composition includes a polymer selected from the group consisting of a ROMA-type polymer including a Ring-Opened Maleic Anhydride repeating unit; COMA-type copolymer including Cyclo-Olefin repeating unit, Maleic Anhydride repeating unit and methacrylate or acrylate repeating unit; and hybrid-type polymer thereof.

5. The method according to claim 3, further comprising baking the photoresist film after the exposure process.

6. The method according to claim 1, wherein the exposure process is performed using an exposure light selected from the group consisting of KrF (248 nm), ArF (193 nm), VUV (157 nm), EUV (13 nm), E-beam, X-ray and ion-beam.

7. The method according to claim 1, wherein the exposure process is performed using an exposure energy ranging from 0.1 to 100 mJ/cm².

8. The method according to claim 1, wherein the exposure process is performed using an exposure mask selectively exposing the first photoresist pattern region.

9. The method according to claim 1, comprising performing the resist flow process to reduce the photoresist pattern by about 5% to about 20% of the minimum size of the photoresist pattern of the unexposed region obtained from the previous step.

10. The method according to claim 1, wherein the resist flow process is performed at or above the glass transition temperature (Tg) of the photoresist polymer.

11. A semiconductor device fabricated by the method of claim 1.
